(19) United States
(12) Patent Application Publication
(10) Pub. No.: US 2026/0123462 A1
(43) Pub. Date: Apr. 30, 2026

(54) SEMICONDUCTOR DEVICES AND METHODS OF MANUFACTURING SEMICONDUCTOR DEVICES

(71) Applicant: Amkor Technology Singapore Holding Pte. Ltd.

(72) Inventor: Mingji Wang, Chandler, AZ (US)

(73) Assignee: Amkor Technology Singapore Holding Pte. Ltd., (omitted)

(21) Appl. No.: 18/932,388

(22) Filed: Oct. 30, 2024

(51) Int. Cl. H01L 23/00; H01L 23/31

(52) U.S. Cl. CPC H10W 70/60; H10W 70/09; H10W 70/6528; H10W 74/111

(57) ABSTRACT

In one example, an electronic device comprises an electronic component including a contact pad. A first dielectric structure can be disposed over the electronic component and can define an opening that exposes the contact pad from the first dielectric structure. A conductive structure can be disposed over the first dielectric structure and coupled to the contact pad. A second dielectric structure can be disposed over the conductive structure and coupled to the contact pad. The second dielectric structure can comprise an outer side. A protruding pad of the conductive structure can include a contoured sidewall protruding from the outer side of the second dielectric structure. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2J show cross-sectional views of an example method for manufacturing an example electronic device.

FIGS. 3A to 3C show cross-sectional views of an example method for manufacturing an example electronic device.

FIGS. 4A and 4B show cross-sectional views of an example method for manufacturing an example electronic device.

FIG. 5 shows a cross-sectional view of an example electronic device mounted on a board.

FIG. 6 shows a cross-sectional view of an example electronic device.

FIG. 7 shows a cross-section of a protruding pad of an example electronic device.

FIG. 8 shows a cross-section of a protruding pad of an example electronic device.

FIG. 9 shows a cross-section of a protruding pad of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction. Descriptions and details of well-known features and techniques may be omitted to avoid unnecessarily obscuring the present disclosure. Elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to a mechanical or electrical coupling.

### DESCRIPTION

An example electronic device comprises an electronic component comprising a contact pad. A first dielectric structure can be disposed over the electronic component and can define an opening that exposes the contact pad from the first dielectric structure. A conductive structure can be disposed over the first dielectric structure and coupled to the contact pad. A second dielectric structure can be disposed over the conductive structure and coupled to the contact pad. The second dielectric structure can comprise an outer side. A protruding pad of the conductive structure can include a contoured sidewall protruding from the outer side of the second dielectric structure.

In various examples, the contoured sidewall comprises a rounded geometry. The contoured sidewall can include a tapered sidewall. The protruding pad can comprise a perimeter substantially coplanar with the outer side of the second dielectric structure. The protruding pad can have a convex geometry. The outer side of the second dielectric structure can include a trench disposed around the protruding pad. The trench can be disposed around the contoured sidewall. An outward terminal of the protruding pad can be coplanar with a portion of the outer side of the second dielectric structure disposed around the trench. An external interconnect can be coupled to the protruding pad and the contoured sidewall. A bond area can be between the protruding pad and the external interconnect. The bond area can have a non-planar geometry.

Another example electronic device can include an electronic component, a dielectric structure disposed over the electronic component, and a conductive structure coupled to the electronic component and extending through the dielectric structure. The conductive structure can comprise a protruding pad having a contoured sidewall protruding from a side of the dielectric structure.

An example method of making an electronic device can include the steps of providing an electronic component including a contact pad, providing a conductive structure coupled to the contact pad, and providing a dielectric structure over the conductive structure. A protruding pad of the conductive structure can comprise a contoured sidewall protruding from an outer side of the dielectric structure.

In various examples, the method can include removing a portion of the dielectric structure from the outer side to leave a trench formed in the outer side and disposed around the protruding pad. A mask can be provided over the dielectric structure. The mask can define an opening that exposes the conductive structure. A conductive material can be provided in the opening to leave the protruding pad protruding from the outer side of the dielectric structure. A portion of the dielectric structure can be removed from the outer side to leave the outer side of the dielectric structure substantially planar and recessed from the protruding pad. A first mold chase and a second mold chase opposite the first mold chase can be provided. The first mold chase can include an elastic film on an inner side, and the protruding pad of the conductive structure can be pressed into the elastic film. A dielectric material can be provided between the first mold chase and second mold chase to form the dielectric structure over the conductive structure. The elastic film can be removed to leave the protruding pad protruding from a side of the dielectric structure.

Other examples are included in the present disclosure. Such examples may be found in the figures, in the claims, or in the description of the present disclosure.

Electronic devices and related methods incorporating protruding pads can yield improved board level reliability (BLR). External interconnects can be coupled to protruding pads having a contoured, non-planar geometry, with the pads protruding above adjacent dielectric structures. The bonds between external interconnects and protruding pads can significantly improve reliability at package interfaces for BGA solder joints, for example, relative to traditional techniques. The bond region between the external interconnect and protruding pad can have an increased surface area relative to the bond region between an external interconnect and a similarly-sized planar pad, which can increase resistance to bond failure. The bond between the protruding pad and external interconnect can include a physical interference to lateral movement, as the protruding pad can extend into the bonded external interconnect.

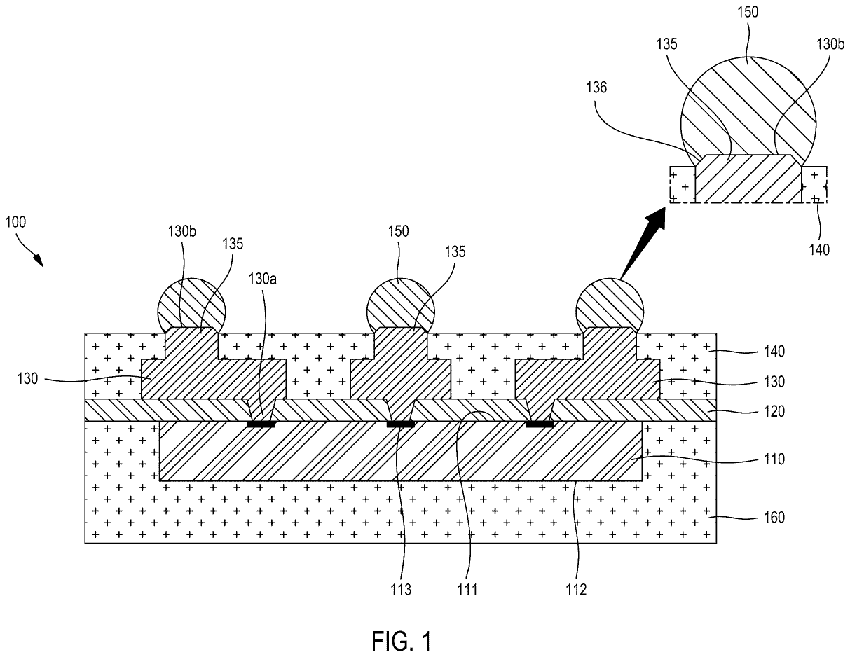

Referring now to FIG. 1, a cross-sectional view of an example electronic device 100 is shown. In the example of FIG. 1, electronic device 100 can comprise electronic component 110, first dielectric structure 120, conductive structure 130, second dielectric structure 140, external interconnects 150, and encapsulant 160.

Electronic component 110 can comprise first side 111, second side 112, and contact pads 113. Conductive structure 130 can comprise inward terminals 130a, outward terminals 130b, and protruding pads 135. Protruding pads 135 can protrude above the upper side of second dielectric structure 140. In some examples, protruding pads 135 can have a tapered geometry with angled sidewalls 136 oriented at an obtuse angle relative to an upper side of second dielectric structure 140.

First dielectric structure 120, conductive structure 130, second dielectric structure 140, external interconnects 150, and encapsulant 160 can be referred to as a semiconductor package. The semiconductor package can provide protection for electronic component 110 from external environments or external exposure. The semiconductor package can provide electrical coupling between electronic component 110 and external electronic components.

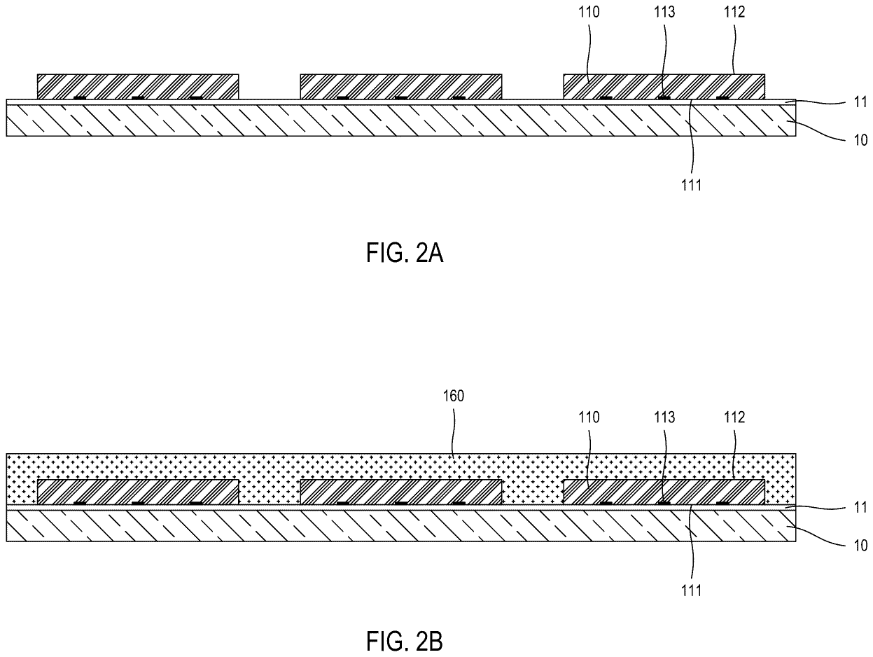

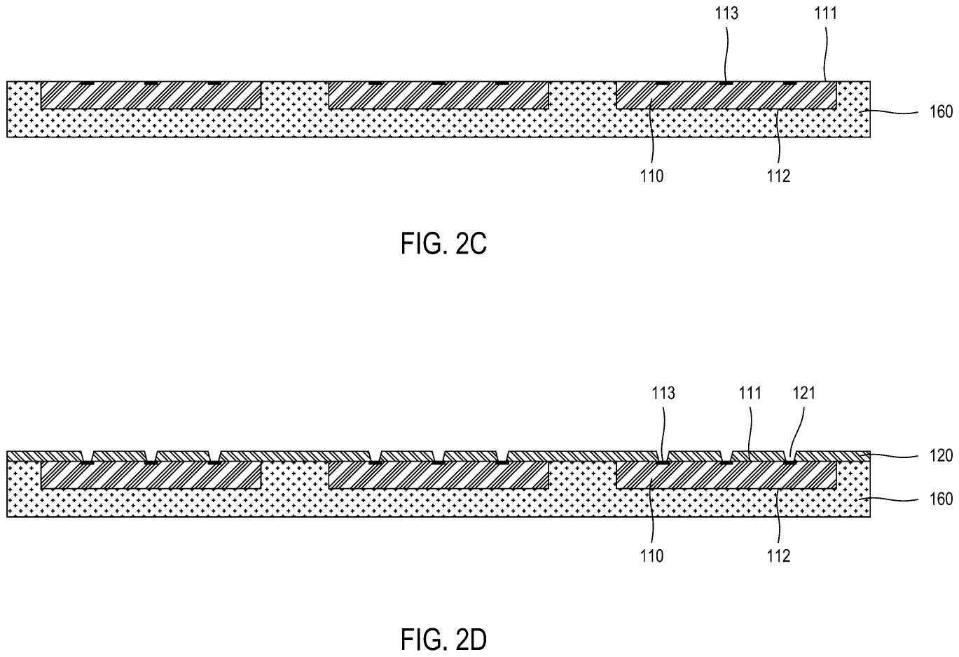

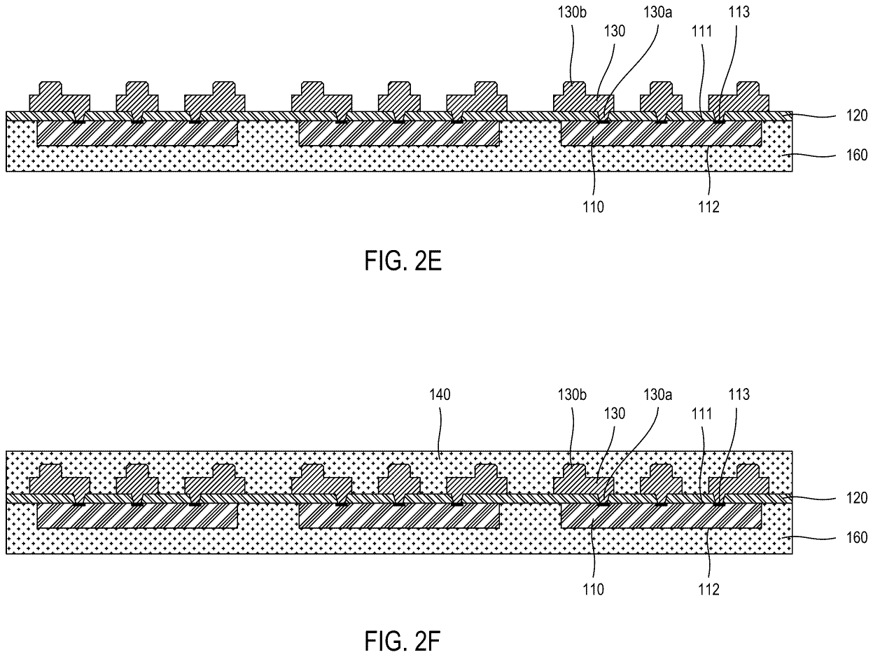

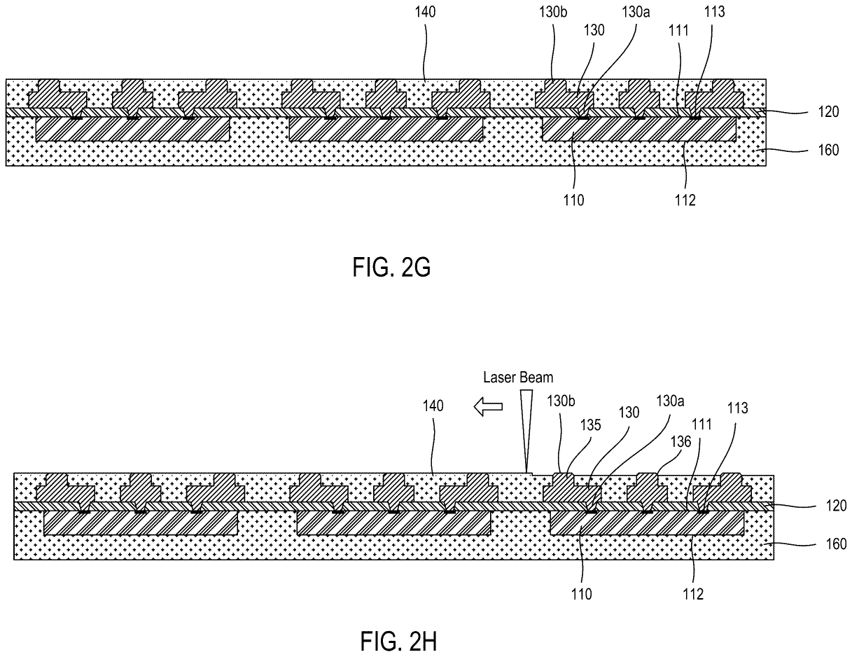

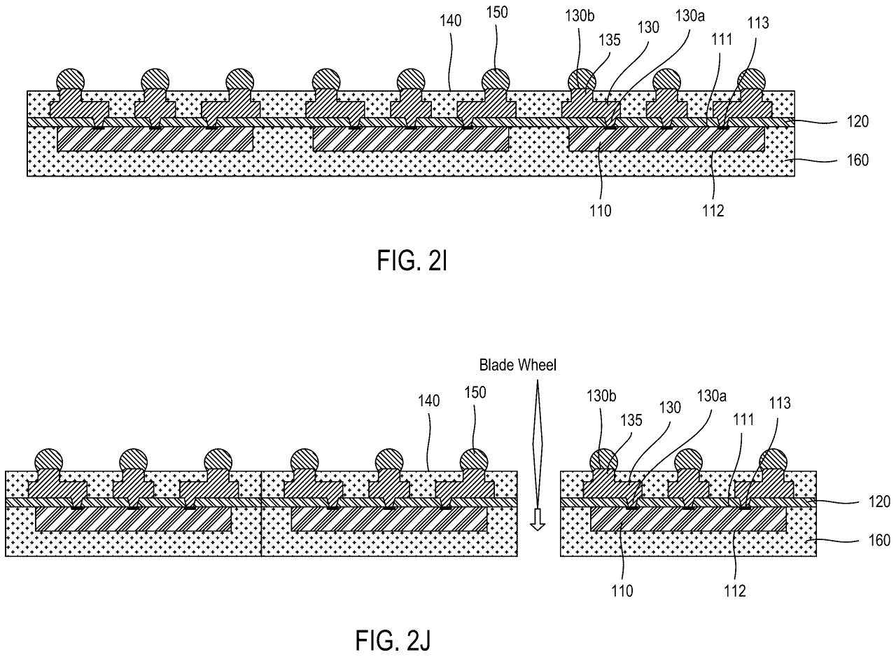

FIGS. 2A to 2J use cross-sectional views to illustrate an example method for manufacturing electronic device 100. FIG. 2A shows a cross-sectional view of electronic device 100 at an early stage of manufacture. In the example shown in FIG. 2A, multiple electronic components 110 can be coupled to carrier 10.

In various examples, carrier 10 can comprise various shapes or characteristics. In some examples, carrier 10 can comprise or be referred to as a wafer support system, a wafer, a board, a panel, or a plate. In some examples, carrier 10 can comprise a wafer material (e.g., a semiconductor material, such as silicon), glass, ceramic, or metal. The thickness of carrier 10 can range from approximately 300 μm (micrometers) to approximately 2,000 μm, and the width of carrier 10 can range from approximately 50 mm (millimeters) to approximately 300 mm. In some examples, the width of carrier 10 can be up to 600 mm. Carrier 10 can support multiple electronic components 110. As used herein with numeric values, the term “approximately” can mean +/−5%, +/−10%, +/−15%, +/−20%, or +/−25%.

In some examples, carrier 10 can comprise temporary bond layer 11 provided on carrier 10. Multiple electronic components 110 can be provided on temporary bond layer 11. In some examples, temporary bond layer 11 can be provided on the upper side of carrier 10 by spin coating, doctor blade coating, casting, painting, spray coating, slot die coating, curtain coating, slide coating, or knife over edge coating, screen printing, pad printing, gravure printing, flexography printing, offset printing, inkjet printing, an intermediate technology between coating and printing, or by direct attachment of a bonding film or bonding tape. In some examples, the temporary bond layer 11 can comprise or be referred to as a temporary bonding film, a temporary bonding tape, or a temporary adhesive coating. For example, the temporary bond layer 11 can be a heat release tape (or film) or an optical release tape (or film), wherein the adhesive strength of temporary bond layer 11 is weakened or removed by heat or light, respectively. In some examples, the adhesive strength of temporary bond layer 11 can be weakened or removed by physical or chemical force.

Each of electronic components 110 can comprise a first side (or first surface) 111, a second side (or second surface) 112 on the opposite side of first side 111, and multiple contact pads 113 provided on first side 111. In some examples, first side 111 of electronic component 110 can comprise or be referred to as a front side, front surface, or an active side. In some examples, second side 112 of electronic component 110 can comprise or be referred to as a back side, back surface, or inactive side. In some examples, contact pads 113 can comprise or be referred to as bond pads, which can be exposed from an inorganic layer (e.g., SiN or SiO2) or redistribution layer (RDL) pads exposed from a dielectric material.

In accordance with various examples, first side 111 of electronic components 10 can be temporarily coupled to temporary bond layer 11 of carrier 10. In some examples, multiple electronic components 110 can be arranged on temporary bond layer 11 in a matrix with rows and columns. A spacing distance between neighboring electronic components 110 can be appropriately adjusted depending on the size of completed electronic device 100. In some examples, the spacing distance (or gap) between the sidewall of a first electronic component 110 and the adjacent sidewall of a neighboring electronic component 110 can be approximately 50 μm to approximately 500 μm. By placing multiple electronic components 110 on carrier 10, the production yield of electronic devices 100 can be improved. In some examples, the thickness of electronic component 110 can range from approximately 50 μm to approximately 500 μm. In some examples, the area (or footprint) of electronic component 110 can range from approximately 0.5 mm by 0.5 mm to 12 mm by 12 mm.

Electronic component 110 can comprise or be referred to as a die, a chip, a package (e.g., one or more encapsulated die), or a passive device. In some examples, electronic component 110 can comprise a digital signal processor (DSP), a network processor, a power management unit, an audio processor, a wireless baseband system on a chip (SoC) processor, a sensor, an application specific integrated circuit, a memory, an antenna on package (AoP), an antenna in package (AiP), a 5G NR mmWave module, a sub-6 GHz RF module, or an integrated passive device (IPD). In some examples, electronic component 110 can perform various functions such as, for example, calculation processing, control processing, data storage, current or voltage amplification, noise filtering, or other functions suitable to electronic components.

FIG. 2B shows a cross-sectional view of electronic device 100 at a later stage of manufacture. In the example shown in FIG. 2B, encapsulant 160 is be provided. Encapsulant 160 can cover multiple electronic components 110 and temporary bond layer 11. In some examples, encapsulant 160 can be provided to a thickness greater than the thickness of electronic components 110, and encapsulant 160 can cover second side 112 of electronic component 110. In some examples, encapsulant 160 can comprise or be referred to as a body, a molding, an epoxy molding compound (EMC), a resin, a filler-reinforced polymer, a B-stage pressed film, or gel.

Encapsulant 160 can be provided by compression molding, transfer molding, liquid-body molding, vacuum lamination, paste printing, film-assisted molding, or any other suitable deposition process. In some examples, compression molding can comprise a method where a flowable resin is first supplied to a mold, electronic components 110 are then input in the mold, and the flowable resin is cured. Transfer molding can comprise a method where a flowable resin is supplied from a gate (supply port) of the mold to the area surrounding electronic components 110 and then cured. Liquid body molding can include a method where electronic components 110 are molded by injecting a liquid resin into a mold. Vacuum lamination can comprise a method where electronic components 110 are molded by attaching a thin sheet of resin using vacuum pressure. Paste printing can include a method where molding is performed by applying resin in the form of a high-viscosity paste to electronic components 110 using a silk screen method. Film-assisted molding can include a method where electronic components 110 are molded by placing a film on the surface of a mold and then injecting resin into the mold.

In various examples, the thickness of encapsulant 160 can range from approximately 200 μm to approximately 600 μm. Encapsulant 160 can serve as a base member supporting formation of first dielectric structure 120, conductive structure 130, and second dielectric structure 140 (FIGS. 2D-2F) during the manufacture of electronic device 100. Encapsulant 160 can protect electronic component 110 from exposure to external elements or the environment and can quickly radiate heat from electronic component 110 outward.

FIG. 2C shows a cross-sectional view of electronic device 100 at a later stage of manufacture. In the example shown in FIG. 2C, carrier 10 is removed. Carrier 10 and temporary bond layer 11 can be removed in any of a variety of ways. For example, temporary bond layer 11 can be removed by applying energy (e.g., heat energy or laser energy) to temporary bond layer 11 or carrier 10. In another example, carrier 10 can be peeled, cut, or pulled away from electronic components 110 and encapsulant 160. In still another example, carrier 10 or temporary bond layer 11 can be ground (or polished) and/or chemically etched. In some examples, after the adhesive force of temporary bond layer 11 is removed or weakened by heat, light, a chemical solution, or physical external force, carrier 10 can be separated from electronic components 110 and encapsulant 160. In some examples, temporary bond layer 11 can be separated from electronic component 110 and encapsulant 160 while remaining attached to carrier 10. Removal of carrier 10 can expose of first side 111 of electronic component 110 and encapsulant 160. In some examples, first side 111 of electronic component 110 and the upper side of encapsulant 160 can be coplanar.

FIG. 2D shows a cross-sectional view of electronic device 100 at a later stage of manufacture. In the example shown in FIG. 2D, first dielectric structure 120 is provided over electronic components 110 and encapsulant 160. First dielectric structure 120 can be provided covering electronic component 110 and encapsulant 160. In some examples, first dielectric structure 120 can comprise or be referred to as a dielectric layer, a coreless layer, or a filler-free layer. For example, first dielectric structure 120 can comprise an electrically insulating material such as polyimide (PI), benzocyclobutene (BCB), polybenzoxazole (PBO), resin, or an Ajinomoto buildup film (ABF). In some examples, first dielectric structure 120 comprises an organic dielectric material. First dielectric structure 120 can be provided on electronic component 110 and encapsulant 160 by spin coating, spray coating, printing, sintering, thermal oxidation, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), plasma vapor deposition (PVD), sheet deposition, vaporization, or any other suitable deposition technique. In some examples, the thickness of first dielectric structure 120 can range from approximately 10 μm to approximately 50 μm.

In accordance with various examples, openings 121 can be provided in first dielectric structure 120. Contact pads 113 of electronic component 110 can be exposed through openings 121 in first dielectric structure 120. In some examples, openings 121 can be provided after first dielectric structure 120 is provided. For example, openings 121 can be provided by providing a mask pattern on the upper side of first dielectric structure 120 and then removing exposed portions first dielectric structure 120 through etching. In some examples, openings 121 can formed using laser ablation.

FIG. 2E shows a cross-sectional view of electronic device 100 at a later stage of manufacture. In the example shown in FIG. 2E, conductive structure 130 is provided. In some examples, conductive structure 130 can be formed by first providing a seed layer for conductive structure 130 on contact pads 113 and first dielectric structure 120. The seed layer can be provided by electroless plating, electrolytic plating, sputtering, PVD, CVD, or any other suitable deposition process. In some examples, the seed layer can comprise titanium (Ti), titanium tungsten (TiW), titanium/copper (Ti/Cu), titanium tungsten/copper (TiW/Cu), or nickel vanadium (NiV). In some examples, the thickness of the seed layer can range from approximately 0.01 μm to approximately 1.0 μm.

In accordance with various examples, after forming the seed layer, a photoresist can be provided over the seed layer. The photoresist can be patterned in accordance with a desired pattern for conductive structure 130. For example, the photoresist can comprise multiple patterns (i.e., openings) with areas of the seed layer being exposed through the openings in the photoresist.

In accordance with various examples, a conductor can be electroplated on the seed layer exposed through the patterned photoresist to provide conductive structure 130 on the seed layer. After deposition of the conductor, the photoresist and the portions of the seed layer not covered by conductive structure 130 are removed (e.g., via etching). In some examples, this process (i.e., seed layer deposition, providing a patterned photoresist, electroplating conductor in the photoresist openings, then removing photoresist and exposed seed layer) can be performed a second time to provide outward terminals 130b.

In some examples, portions of conductive structure 130 coupled to contact pads 113 through openings 121 of first dielectric structure 120 can be referred to as inward terminals 130a, and portions of conductive structure 130 where external interconnects 150 are to be connected later can be referred to as outward terminals 130b. Conductive structure 130 can comprise or be referred to as one or more conductive layers defining signal distribution elements such as, for example, traces, vias, pads, conductive paths, and under bumped metals (UBMs).

In various examples, conductive structure 130 can comprise copper, aluminum, gold, silver, nickel, palladium, or platinum. Conductive structure 130 can be provided through processes such as, for example, electroplating, electroless plating, chemical vapor deposition (CVD), metal organic chemical vapor deposition (MOCVD), sputtering or physical vapor deposition (PVD), atomic layer deposition (ALD), plasma vapor deposition, printing, or screen printing. The thickness of conductive structure 130 can range from approximately 10 μm to approximately 30 μm. Conductive structure 130 can transmit electrical signals in horizontal and vertical directions. In some examples, the diameters of inward terminals 130a can range from approximately 10 μm to approximately 40 μm. Inward terminals 130a can electrically connect contact pads 113 of electronic component 110 and conductive structure 130. In some examples, the diameters of outward terminals 130b can range from approximately 200 μm to approximately 250 μm. Outward terminals 130b can electrically connect external interconnects 150 and conductive structure 130.

Although the example of FIG. 2E depicts first dielectric structure 120 as a single layer and conductive structure 130 as a single layer, first dielectric structure 120 or conductive structure 130 can also comprise multi-layer structures. In some examples, in order to provide a multilayer structure, the process of providing the dielectric structure and the conductive structure can be repeated multiple times. In some examples, first dielectric structure 120 and conductive structure 130 can comprise multiple layers interleaved with one another. Additionally, conductive structure 130 and second dielectric structure 140, which will be described below, can also be interleaved with one another.

FIG. 2F shows a cross-sectional view of electronic device 100 at a later stage of manufacture. In the example shown in FIG. 2F, second dielectric structure 140 can be provided. Second dielectric structure 140 can be provided on conductive structure 130 and first dielectric structure 120. In some examples, a height of second dielectric structure 140 above dielectric structure 120 can be greater than a height of conductive structure 130 above dielectric structure 120. Second dielectric structure 140 can cover conductive structure 130. In some examples, second dielectric structure 140 can comprise or be referred to as a body, a molding, an epoxy molding compound (EMC), a resin, a filler-reinforced polymer, a B-stage pressed film, or gel. Second dielectric structure 140 can comprise one or more of a variety of encapsulating materials. In some examples, second dielectric structure 140 can comprise any material selected from various encapsulating or molding materials (e.g., resins, polymers, polymer composites, polymers with fillers, epoxy resins, epoxy resins with fillers, epoxy acrylates with fillers, silicone resins, or combinations thereof. In some examples, second dielectric structure 140 can be provided by compression molding, transfer molding, liquid body molding, vacuum lamination, paste printing, or film assisted molding. In some examples, second dielectric structure 140 and encapsulant 160 can comprise the same material (e.g., an encapsulant or mold material).

In some examples, second dielectric structure 140 can comprise inorganic dielectric materials (e.g., Si3N4, SiO2, SiON, SiN, oxide, nitride, or combinations thereof). In some examples, second dielectric structure 140 can comprise organic dielectric materials (e.g. polymers, PI, BCB, PBO, bismaleimide triazine (BT)). In some examples, second dielectric structure 140 can be provided by spin coating, spray coating, printing, sintering, thermal oxidation, PVD, CVD, MOCVD, ALD, LPCVD, PECVD, plasma vapor deposition, sheet deposition, vaporization, or any other suitable deposition process.

The thickness of second dielectric structure 140, before grinding, can range from approximately 50 μm to approximately 200 μm. Second dielectric structure 140 can protect conductive structure 130 from exposure to external elements or the environment and can quickly radiate heat from conductive structure 130 outward.

In some examples, first dielectric structure 120, conductive structure 130, and second dielectric structure 140 can be referred to as a substrate. In some examples, the substrate can be a redistribution layer (“RDL”) substrate. RDL substrates can comprise one or more conductive redistribution layers and one or more dielectric layers that (a) can be formed layer by layer over an electronic device to which the RDL substrate is coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process.

RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask.

The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si3N4), silicon oxide (SiO2), or SiON.

The inorganic dielectric layer(s) can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4, and these types of RDL substrates can be referred to as coreless substrates.

In some examples, the substrate can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF).

A pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

FIG. 2G shows a cross-sectional view of electronic device 100 at a later stage of manufacture. In the example shown in FIG. 2G, a grinding process can be performed. By grinding and removing some areas of second dielectric structure 140, the thickness of second dielectric structure 140 can be reduced. In some examples, after grinding the upper side of second dielectric structure 140 to a reference thickness using a grinding pad with relatively large abrasive particles, the upper side of second dielectric structure 140 can be finely ground through a grinding pad with relatively small abrasive particles. In some examples, after grinding, the thickness of second dielectric structure 140 can range from approximately 50 μm to approximately 100 μm. By the grinding process, some areas of conductive structure 130 (for example, outward terminals 130b) can be exposed through second dielectric structure 140. In some examples, the upper sides of outward terminals 130b of conductive structure 130 and the upper side of second dielectric structure 140 can be coplanar.

FIG. 2H shows a cross-sectional view of electronic device 100 at a later stage of manufacture. In the example shown in FIG. 2H, a laser ablation process can be performed. By providing laser beams on second dielectric structure 140, the areas of second dielectric structure 140 around the lateral sides of outward terminals 130b can be removed. The removal depth of second dielectric structure 140 can range from approximately 10 μm to approximately 25 μm. In some examples, by removing some areas of second dielectric structure 140, outward terminals 130b can protrude from the upper side (or distal side) of second dielectric structure 140 by heights ranging from approximately 10 μm to approximately 25 μm. In some examples, the area of outward terminal 130b protruding from the upper side of second dielectric structure 140 can comprise or be referred to as protruding pad 135. Protruding pad 135 exposed from second dielectric structure 140 can be substantially circular when viewed from the top. Protruding pads 135 can have a non-planar, contoured geometry comprising angled sidewalls 136 extending above the upper side of second dielectric structure 140. Angled sidewalls 136 can be oriented at an obtuse angle relative to the upper side of second dielectric structure 140.

In some examples, the laser ablation process can comprise the steps of placing an electronic device on a stage, generating laser beams, X-Y scanning the laser beams over second dielectric structure 140, focusing the laser beams scanned over second dielectric structure 140 into a small laser beam spot, suctioning and removing dust generated when some areas of second dielectric structure 140 are removed, and adjusting the stage height according to the thickness of an electronic device.

In accordance with various examples, laser beams can be generated as an energy source to selectively remove portions of second dielectric structure 140. As the laser beams generated in the laser beam generation step, laser beams of various wavelengths suitable for removing some areas of second dielectric structure 140 can be used. In some examples, a laser beam having a near-infrared wavelength region (e.g., a wavelength of approximately 1.0 μm to approximately 1.1 μm) can be suitable to selectively remove a portion of second dielectric structure 140. Continuing the near-infrared example, little reaction occurs with outward terminals 130b or protruding pad 135, made of metal materials, while having good reactivity between the laser beam and second dielectric structure 140. Using fiber lasers in the above-described wavelength range can reduce the need for optical alignment and can sustain prolonged and reliable use due to longevity of consumable optical components.

In accordance with various examples, the dust suctioning step can comprise removing dust generated when portions of second dielectric structure 140 are destroyed and removed by laser beams. In some examples, for more efficient dust removal, a gas injection area can be configured to spray gas from the opposite side of a dust suction area to the upper side of second dielectric structure 140 to guide the dust evaporated from second dielectric structure 140 to the dust suction area. When outward terminals 130b or protruding pad 135 contain a copper material vulnerable to oxidation, thermal oxidation by the laser beam can occur. The thermal oxidation effect caused by the laser beam can be reduced by spraying an inert gas such as nitrogen (N2) or argon (Ar) from the gas injection area.

Protruding pad 135 protruding upward from second dielectric structure 140 can be provided through such a laser ablation process in various examples, though other techniques described herein can also be used to provide protruding pad 135. As described above, the thickness of protruding pad 135 protruding from second dielectric structure 140 can range from approximately 10 μm to approximately 25 μm. In accordance with various examples, the upper side of protruding pad 135 can be defined as outward terminals 130b. The bonding area or contact area between protruding pad 135 and external interconnects 150 (described below) can be increased by protruding pad 135 protruding upward from second dielectric structure 140.

FIG. 2I shows a cross-sectional view of electronic device 100 at a later stage of manufacture. In the example shown in FIG. 2I, external interconnects 150 can be provided. External interconnects 150 can be coupled to protruding pad 135 and outward terminals 130b. In some examples, external interconnects 150 can comprise tin (Sn), silver (Ag), lead (Pb), copper (Cu), Sn—Pb, Sn₃₇—Pb, Sn₉₅—Pb, Sn—Pb—Ag, Sn—Pb—Bi, Sn—Cu, Sn—Ag, Sn—Au, Sn—Bi, Sn—Ag—Cu, Sn—Ag—Bi, Sn—Zn, or Sn—Zn—Bi. In some examples, after temporarily placing a conductive material containing solder on protruding pad 135 and outward terminals 130b through a ball drop method, external interconnects 150 can be completed through a reflow process. External interconnects 150 can be referred to as conductive balls, solder balls, conductive bumps, or conductive caps on protruding pad 135 and outward terminals 130b.

In some examples, external interconnects 150 can surround the exposed portion of protruding pad 135 and outward terminals 130b. External interconnects 150 can be in contact with second dielectric structure 140 in an area around protruding pads 135. In some examples, external interconnects 150 can surround a portion of protruding pad 135 and outward terminals 130b and can be spaced apart from second dielectric structure 140. In some examples, the diameter of external interconnects 150 can range from approximately 200 μm to approximately 300 μm. In some examples, external interconnects 150 can be referred to as external input/output terminals of electronic device 100. External interconnects 150 can be electrically connected to electronic component 110 through conductive structure 130. Protruding pad 135 being disposed above the upper side of second dielectric 140 increases the surface area of the bond region (or interface) between external interconnect 150 and protruding pad 135, which can increase resistance to bond failure.

FIG. 2J shows a cross-sectional view of electronic device 100 at a later stage of manufacture. In the example shown in FIG. 2J, a sawing or singulation process can be performed. In some examples, individual electronic device 100 can be separated by a sawing tool, such as a diamond blade wheel or laser beam. In some examples, sawing can be performed by cutting through second dielectric structure 140, first dielectric structure 120, and encapsulant 160. Accordingly, the lateral sides of second dielectric structure 140, first dielectric structure 120, and encapsulant 160 can be coplanar after singulation. In some examples, conductive structure 130 can also be sawed during the sawing process, and accordingly, the lateral sides of the second dielectric structure 140, first dielectric structure 120, conductive structure 130, and encapsulant 160 can be coplanar.

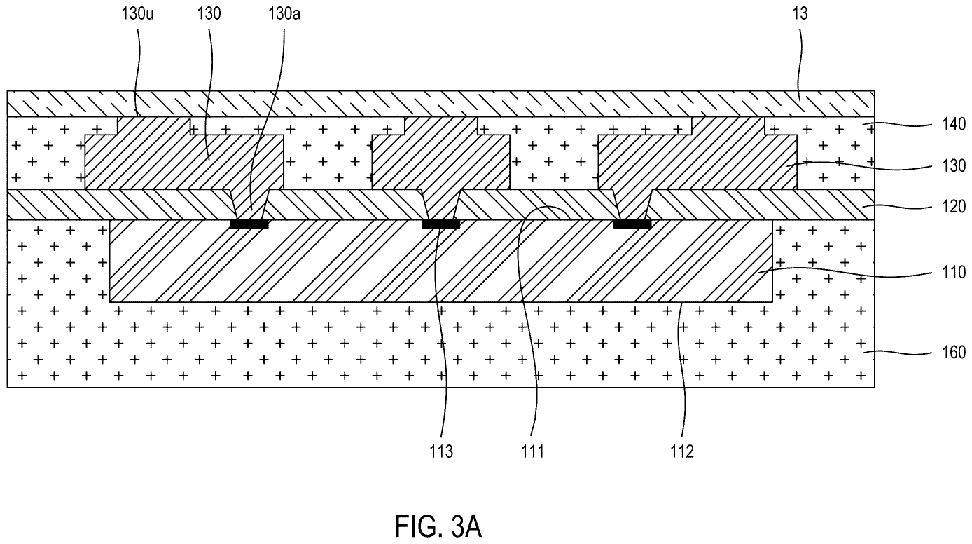

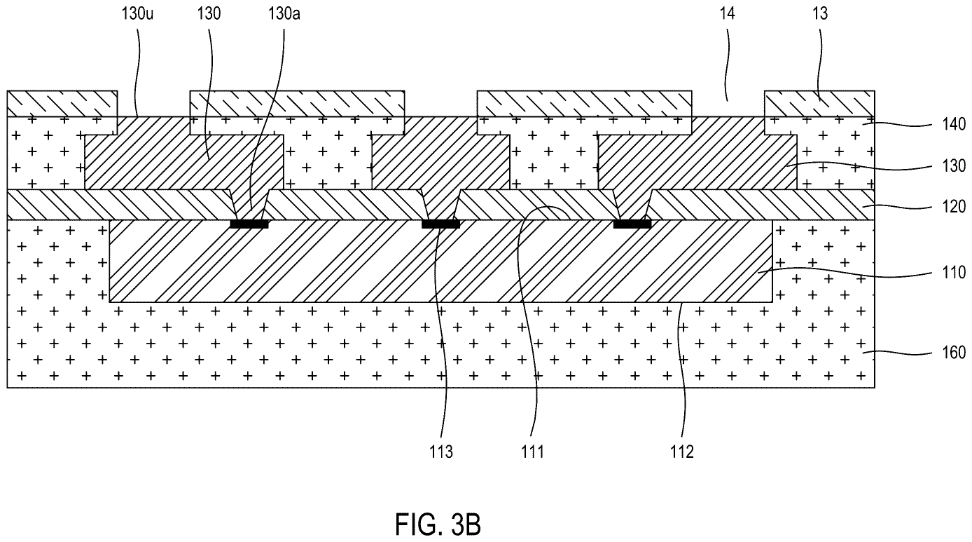

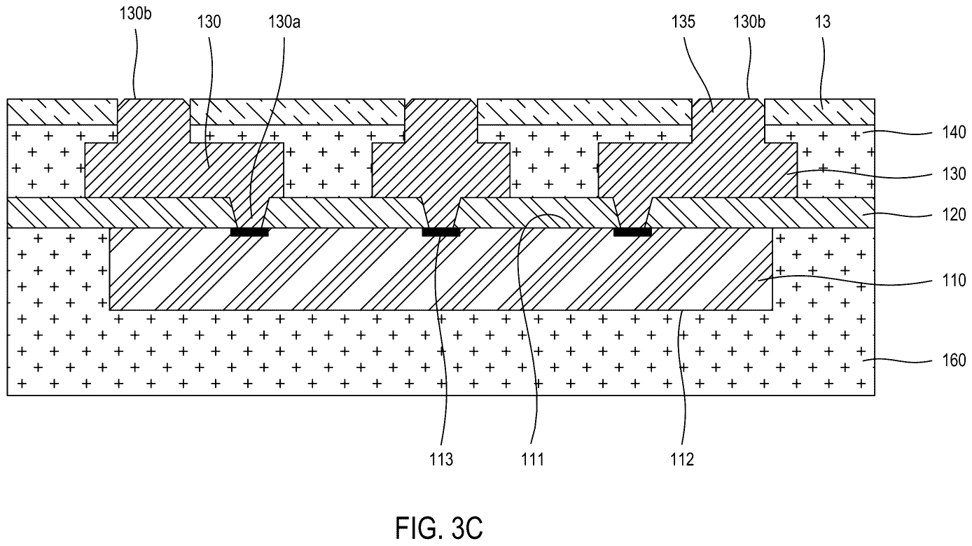

FIGS. 3A to 3C show an example method for manufacturing electronic device 100 using cross-sectional views. FIG. 3A shows a cross-sectional view of electronic device 100 at a later stage of manufacture. For example, the step depicted in FIG. 3A may follow after processing steps depicted in FIGS. 2A-2G.

In the example shown in FIG. 3A, after grinding second dielectric structure 140, photoresist 13 can be provided on second dielectric structure 140. Photoresist 13 can be provided on the upper side of second dielectric structure 140 and on the upper side 130u of conductive structure 130. Photoresist 13 can be provided by spin coating, doctor blade coating, casting, painting, spray coating, slot die coating, curtain coating, slide coating, knife over edge coating, screen printing, pad printing, gravure printing, flexography printing, offset printing, an inkjet printing method, an intermediate technology between coating and printing, by attachment of a film, or any other suitable deposition method.

FIG. 3B shows a cross-sectional view of electronic device 100 at a later stage of manufacture. In the example shown in FIG. 3B, openings 14 can be provided in photoresist 13 by a photo etching process. In some examples, by irradiating light after a mask is placed on photoresist 13, some areas of photoresist 13 can be exposed to light. By developing a photosensitive area or a non-photosensitive area of photoresist 13, openings 14 can be provided, for example, at locations corresponding to upper side 130u (or pads) of conductive structure 130. Upper side 130u (or pads) of conductive structure 130 can be exposed through openings 14 of photoresist 13.

FIG. 3C shows a cross-sectional view of electronic device 100 at a later stage of manufacture. In the example shown in FIG. 3C, protruding pad 135 can be provided. In some examples, protruding pad 135 can be provided through electroplating, electroless plating, CVD, MOCVD, sputtering or PVD, ALD, plasma vapor deposition, printing, or screen printing. The thickness of protruding pad 135 (i.e., the portion of conductive structure 130 that is located above the upper side of second dielectric 140) can range from approximately 10 μm to approximately 25 μm as measured from the upper side of second dielectric structure 140. Protruding pad 135 can have similar or identical structures and characteristics to protruding pad 135 as described in FIG. 2H. After forming protruding pad 135, photoresist 13 can be removed.

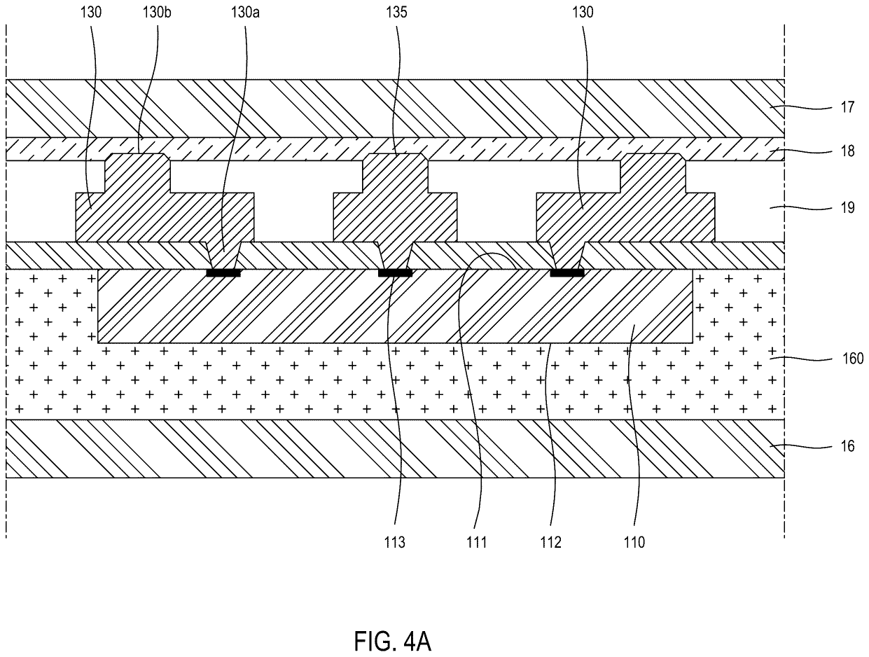

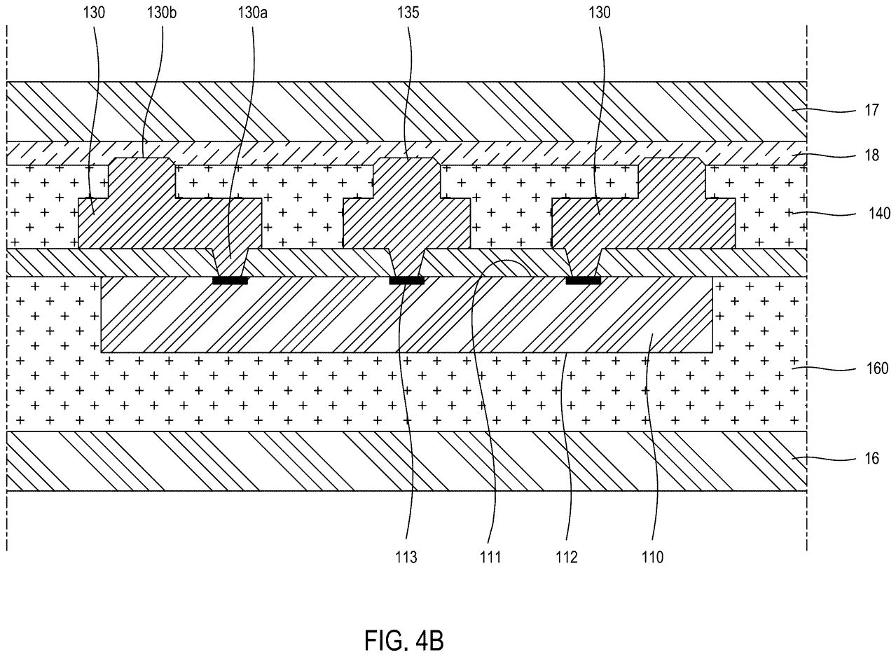

FIGS. 4A and 4B show cross-sectional views of an example method for manufacturing an example electronic device 100. FIG. 4A shows a cross-sectional view of electronic device 100 at a later stage of manufacture. For example, the step depicted in FIG. 4A may follow after processing steps depicted in FIGS. 2A-2E.

In the example shown in FIG. 4A, after providing conductive structure 130, encapsulated electronic components 110 can be interposed between lower mold chase 16 and upper mold chase 17. The lower side of encapsulant 160 can be located on the upper side of lower mold chase 16. Conductive structure 130 can be coupled to the lower side of upper mold chase 17 through elastic film 18. In some examples, the upper sides of outward terminals 130b of conductive structure 130 can approach the lower side of upper mold chase 17 and extend into elastic film 18. In some examples, some areas of outward terminals 130b can be inserted to elastic film 18 to a desired depth (e.g., the desired height of protruding pad 135). In some examples, the depths of outward terminals 130b inserted to elastic film 18 can range from approximately 10 μm to approximately 25 μm. In some examples, gap or volume 19 can be provided between elastic film 18 and conductive structure 130 and between elastic film 18 and first dielectric structure 120.

FIG. 4B shows a cross-sectional view of electronic device 100 at a later stage of manufacture. In the example shown in FIG. 4B, second dielectric structure 140 can be provided. In some examples, second dielectric structure 140 can be provided to fill gap 19 between first dielectric structure 120, conductive structure 130 and elastic film 18. In some examples, second dielectric structure 140 can be provided in gap 19 in molten form. In some examples, second dielectric structure 140 can have a composition and characteristics similar to or identical to encapsulant 160. Second dielectric structure 140 can be provided to gap 19 between first dielectric structure 120, conductive structure 130, and elastic film 18 by transfer molding. In some examples, the flowable resin similar or identical to encapsulant 160 can be supplied from the gate around conductive structure 130 and then cured. The thickness of second dielectric structure 140 can range from approximately 50 μm to approximately 100 μm. Second dielectric structure 140 can protect conductive structure 130 from exposure to external elements or the environment. Some areas of outward terminals 130b coupled to elastic film 18 may be exposed from second dielectric structure 140. Portions of outward terminals 130b that pressed into elastic film 18 can protrude above the upper side of second dielectric structure 140.

After curing second dielectric structure 140, electronic device 100 can be separated from upper mold chase 17 and lower mold chase 16. During the separation process, elastic film 18 is also removed, thereby leaving portions of conductive structure 130 (i.e., outward terminals 130bs and protruding pad 135) exposed from second dielectric structure 140. The upper side of second dielectric structure 140 can be lower than the upper side of protruding pad 135, and accordingly, the upper side of protruding pad 135 can protrude from the upper side of second dielectric structure 140. Protruding pad 135 can have similar or identical structures and characteristics to protruding pad 135 as described in FIG. 2H

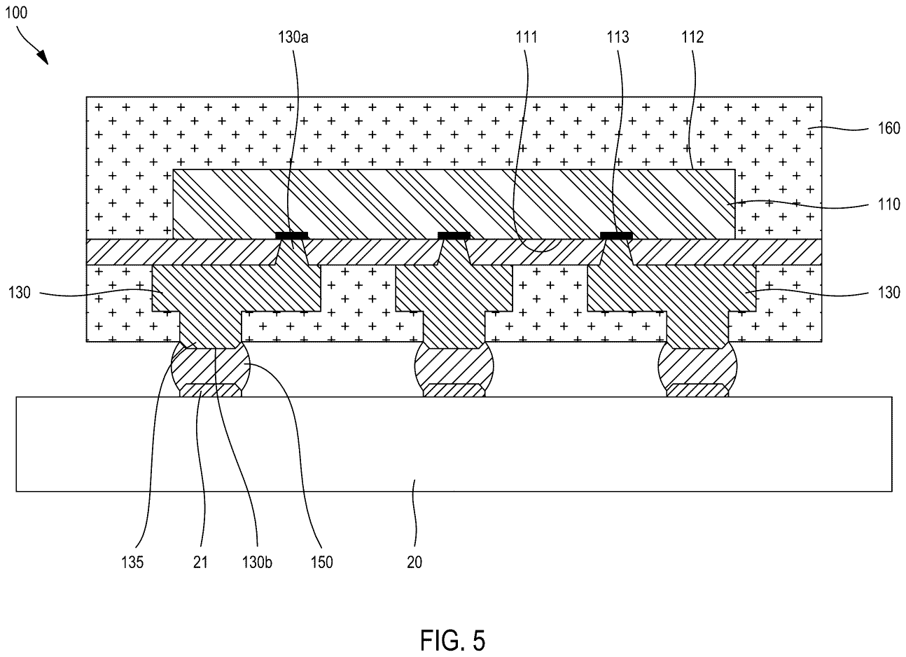

FIG. 5 shows a cross-sectional view of an example electronic device 100. In the example shown in FIG. 5, electronic device 100 can be mounted on external board 20. External interconnects 150 of electronic device 100 can be coupled to external pad 21 of external board 20. As described above, since electronic device 100 can be connected through external interconnects 150 surrounding protruding pad 135 and outward terminals 130b of conductive structure 130, connection areas between external interconnects 150, protruding pad 135, and outward terminals 130b can be increased relative to flat bonding interfaces. Accordingly, board level reliability of electronic device 100 with respect to external board 20 can be improved. In some examples, board level reliability performance can be improved at upper interfaces between external interconnects 150 and outward terminals 130b, and significant improvements can be made in package interfaces to solder joints. In some examples, depending on the design of external pad 21 of external board 20, board level reliability performance in lower interfaces between external interconnects 150 and external pad 21 can also be improved. In some examples, external pad 21 of external board 20 can also have a similar or identical structure to protruding pad 135, and thus the board level reliability performance for the lower interface can also be improved. In some examples external pad 21 can be coplanar with the upper side of board 20.

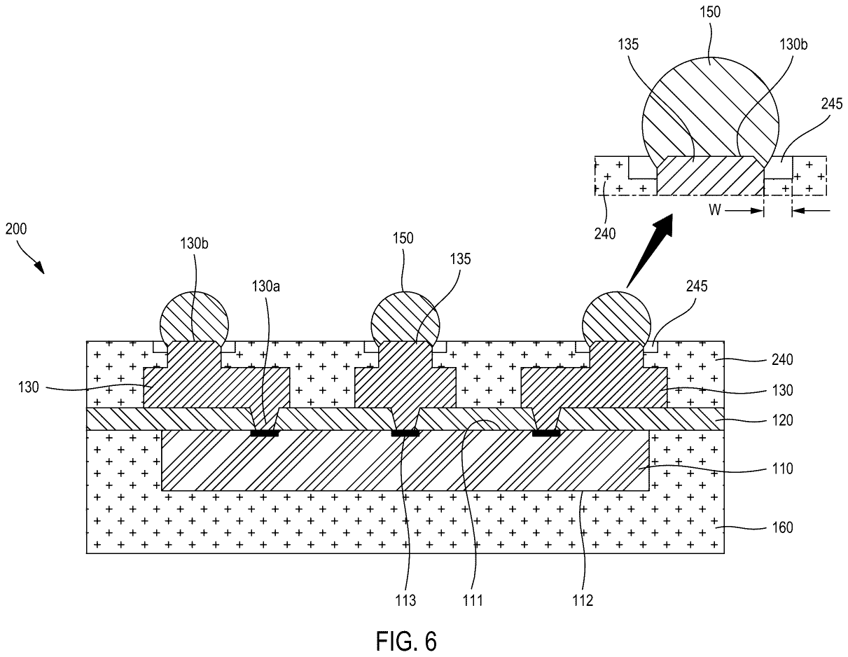

FIG. 6 shows a cross-sectional view of an example electronic device 200. In the example shown in FIG. 6, electronic device 200 can be similar to electronic device 100 shown in FIG. 1, except that second dielectric structure 240 is provided with recesses 245 defined in second dielectric structure 240. Second dielectric structure 240 can comprise recesses 245 provided around outward terminals 130b. Recesses 245 can comprise or be referred to as wells or trenches.

In some examples, recesses 245 can be provided in a manner similar to the laser ablation process described above with reference to FIG. 2H. In some examples, after grinding second dielectric structure 240, only some areas of second dielectric structure 240 around outward terminals 130b can be laser-ablated. In some examples, each of recesses 245 can be defined by inner sidewalls of second dielectric structure 240 in an annulus or ring-shape with respect to outward terminals 130b as viewed from above. As described above, after grinding, the upper sides of outward terminals 130b can be coplanar with the upper side of second dielectric structure 240, and thus the upper side of protruding pad 135 exposed from second dielectric structure 240 by recesses 245 can also be coplanar with the upper side of second dielectric structure 240. In some examples, the depth of recess 245 can range from approximately 10 μm to approximately 30 μm. In some examples, the width W of recess 245, as measured between the lateral side of protruding pad 135 and the sidewall of recess 245, can range from approximately 10 μm to approximately 30 μm. External interconnects 150 can be coupled to outward terminals 130b while surrounding protruding pad 135 with a portion of external interconnects 150 extending into recesses 245. In some examples, external interconnects 150 can be spaced apart from the interior sidewalls of second dielectric structure 240 defining recesses 245.

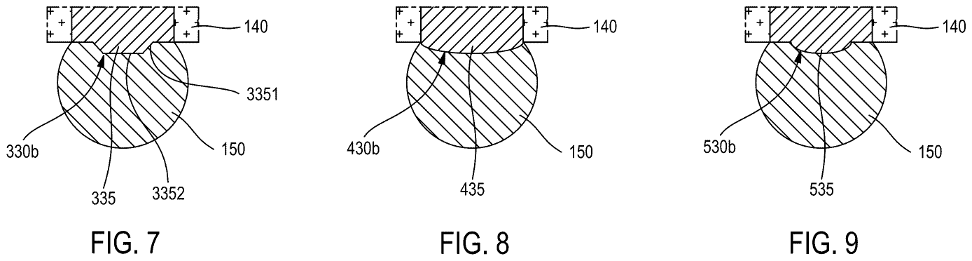

FIG. 7 shows a cross-section of a protruding pad 335 of an example electronic device. In the example shown in FIG. 7, protruding pad 335 can protrude from the center of one side of outward terminal 330b. In some examples, protruding pad 335 can comprise side portion 3351 inclined and extending from outward terminal 330b and lower side 3352 connected to inclined side portion 3351. Side portion 3351 can also be described as tapered, angled, pitched, or sloped relative to the outer (or distal) side of second dielectric structure 140. Lower side 3352 can be substantially parallel to the distal side of second dielectric structure 140 in some examples. In some examples, the width or diameter of protruding pad 335 can be less than the width or diameter of outward terminal 330b. Protruding pad 335 can have a non-planar, contoured geometry. In some examples, this type of protruding pad 335 can be provided by performing plating in a configuration in which the diameter of an opening in a mask is made smaller than the diameter of outward terminal 330b, with the perimeter region of outward terminal 330b is covered by the mask. Plating can result in forming the central portion of protruding pad 335 in the opening defined by the mask over the central portion of outward terminal 330b, thus leaving the perimeter region of outward terminal 330b substantially coplanar with second dielectric structure 140. The angled or tapered walls of side portion 3351 can result from plating or other metal deposition processes, in some examples without subsequent smoothing or flattening steps. In some examples, external interconnects 150 can be coupled to a perimeter region of outward terminal 330b substantially coplanar with second dielectric structure 140, inclined side portion 3351 of protruding pad 335, and planar lower side 3352 of protruding pad 335. A contact region or contact area between external interconnect 150 and protruding pad 335 can be non-planar and contoured to the exposed side of protruding pad 335.

FIG. 8 shows a cross-section of a protruding pad 435 of an example electronic device. In the example shown in FIG. 8, protruding pad 435 can protrude from an outer (or distal) side of outward terminal 430b. In some examples, the width of protruding pad 435 can taper in portions further downward (in the orientation of FIG. 8) from the level of second dielectric structure 140. Protruding pad 435 can have a rounded geometry similar to a hemispherical geometry, a meniscus-like geometry, or a convex geometry. Protruding pad 435 can protrude or bulge from a perimeter region that begins at a height of second dielectric structure 140. In some examples, protruding pad 435 can have a side of a perimeter region closer to the height of second dielectric structure 140 than a side of a central region of protruding pad 435. In some examples, protruding pad 435 can be provided by plating excess metal to form the outer side of outward terminal 430b without performing typical smoothing or leveling steps. Plating excess metal without smoothing can provide protruding pad 435 having a rounded, convex, or bulbous geometry. Protruding pad 435 can comprise a non-planar, contoured geometry. In some examples, external interconnects 150 can be coupled to the round lower side of protruding pad 435.

FIG. 9 shows a cross-section of a protruding pad 535 of an example electronic device. In the example shown in FIG. 9, protruding pad 535 can protrude from the center of one side of outward terminal 530b. In some examples, protruding pad 535 can comprise a lower side rounded and convex in an outward direction from outward terminal 530b. In some examples, the width of protruding pad 535 can be smaller than the width of outward terminal 530b. Outward terminal 530b can comprise a flat ring disposed around protruding pad 535 at a lower side. In some examples, protruding pad 535 can be provided by plating excessive metal in a state where the diameter of the mask opening is made smaller than the diameter of outward terminal 530b. In some examples, external interconnects 150 can be coupled to a planar lower side of outward terminal 530b and a round lower side of protruding pad 535.

Various examples of electronic devices include protruding pads coupled to a flowable material. The protruding pads can improve reliability of the interface between the pad and interconnect, thus improving BLR.

The present disclosure includes reference to certain examples, however, it will be understood by those skilled in the art that various changes may be made and equivalents may be substituted without departing from the scope of the disclosure. Modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
an electronic component comprising a contact pad;
a first dielectric structure disposed over the electronic component and defining an opening that exposes the contact pad from the first dielectric structure;
a conductive structure disposed over the first dielectric structure and coupled to the contact pad;
a second dielectric structure disposed over the conductive structure and coupled to the contact pad, the second dielectric structure comprising an outer side; and
a protruding pad of the conductive structure comprising a contoured sidewall protruding from the outer side of the second dielectric structure.

2. The electronic device of claim 1, wherein the contoured sidewall comprises a rounded geometry.

3. The electronic device of claim 1, wherein the contoured sidewall comprises a tapered sidewall.

4. The electronic device of claim 1, wherein the protruding pad comprises a perimeter substantially coplanar with the outer side of the second dielectric structure.

5. The electronic device of claim 1, wherein the protruding pad comprises a convex geometry.

6. The electronic device of claim 1, wherein the outer side of the second dielectric structure comprises a trench disposed around the protruding pad.

7. The electronic device of claim 6, wherein the trench is disposed around the contoured sidewall.

8. The electronic device of claim 6, wherein an outward terminal of the protruding pad is coplanar with a portion of the outer side of the second dielectric structure disposed around the trench.

9. The electronic device of claim 1, further comprising an external interconnect coupled to the protruding pad and the contoured sidewall.

10. The electronic device of claim 9, further comprising a bond area between the protruding pad and the external interconnect, the bond area having a non-planar geometry.

11. An electronic device, comprising:
an electronic component;
a dielectric structure disposed over the electronic component; and
a conductive structure coupled to the electronic component and extending through the dielectric structure,
wherein the conductive structure comprises a protruding pad having a contoured sidewall protruding from a side of the dielectric structure.

12. The electronic device of claim 11, wherein the contoured sidewall comprises a rounded geometry.

13. The electronic device of claim 11, wherein the contoured sidewall comprises a tapered sidewall.

14. The electronic device of claim 11, wherein the protruding pad comprises a perimeter substantially coplanar with the side of the dielectric structure.

15. The electronic device of claim 11, wherein the protruding pad comprises a convex geometry.

16. A method of making an electronic device, comprising:
providing an electronic component including a contact pad;
providing a conductive structure coupled to the contact pad; and
providing a dielectric structure over the conductive structure,
wherein a protruding pad of the conductive structure comprises a contoured sidewall protruding from an outer side of the dielectric structure.

17. The method of claim 16, further comprising removing a portion of the dielectric structure from the outer side to leave a trench formed in the outer side and disposed around the protruding pad.

18. The method of claim 16, further comprising:
providing a mask over the dielectric structure, wherein the mask defines an opening that exposes the conductive structure; and
providing a conductive material in the opening to leave the protruding pad protruding from the outer side of the dielectric structure.

19. The method of claim 16, further comprising removing a portion of the dielectric structure from the outer side to leave the outer side of the dielectric structure substantially planar and recessed from the protruding pad.

20. The method of claim 16, further comprising:
providing a first mold chase and a second mold chase opposite the first mold chase, wherein the first mold chase includes an elastic film on an inner side of the first mold chase, wherein the protruding pad of the conductive structure is pressed into the elastic film;
providing a dielectric material between the first mold chase and second mold chase to form the dielectric structure over the conductive structure; and
removing the elastic film to leave the protruding pad protruding from a side of the dielectric structure.
